(19) United States
(12) Patent Application Publication
(10) Pub. No.: US 2026/0347193 A1
(43) Pub. Date: Nov. 5, 2026

(54) A METHOD FOR SURFACE-MODIFYING CARBONACEOUS PARTICLES

(71) Applicant: VIANODE AS, Oslo (NO)

(72) Inventors: Bridget Catherine DEVENEY, Kristiansand (NO); Zhanlei TANG, Kristiansand (NO); Navaneethan MUTHUSWAMY, Kristiansand (NO)

(21) Appl. No.: 19/486,867

(22) PCT Filed: May 22, 2024
(86) PCT No.: PCT/NO2024/050124

§ 371 Date: Nov. 21, 2025

(30) Foreign Application Priority Data
May 24, 2023 (NO) 20230598

(51) Int. Cl. C01B 32/21; H01M 4/587

(52) U.S. Cl. CPC C01B 32/21; H01M 4/587; C01P 2004/61; C01P 2006/12; C01P 2006/40

(57) ABSTRACT

The invention describes a method for surface-modifying carbonaceous particles, the method comprising the steps of agglomerating carbonaceous particles by mixing the carbonaceous particles with a non-carbonized bio-based binding agent, heating the agglomerated carbonaceous particles at a rate of at least 25° C. per minute to a temperature T, and carbonizing the agglomerated carbonaceous particles at the temperature T in a gaseous environment comprising a hydrocarbon-containing gas The invention also describes a graphite anode material.

### FIELD OF INVENTION

The invention relates to the field of surface modification of carbon containing particles.

### BACKGROUND

Graphite particles are today extensively employed as an anode material in lithium-ion batteries. However, in order to obtain batteries with a low initial capacity loss, adequate cyclability and fast-charging performance, the graphite particles often need to be surface modified prior to being used in anode production. Surface modification of graphite particles is generally performed by agglomerating the graphite particles with an amorphous carbon-based binder followed by subjecting the agglomerated graphite particles to carbonization. The most common source of amorphous carbon-based binder is currently the fossil-based pitch.

Bio-based binding agents have in recent years received increasing attention for their potential to replace pitch as a binder in surface modification of graphite particles. Bio-based binders are not only preferred to pitch due to their reduced environmental footprint, but also because of the associated reduction of health risks during handling.

The employment of bio-based binding agents in surface modification of graphite carbon has, however, proven to be technologically demanding. A challenge in using bio-based binding agents in surface modification of graphite particles is related to the chemical structure and oxygen content of most bio-based binding agents. During carbonization of bio-based binding agents, theses tend to release O-species and low stability functional groups that further lead to defect formation. The latter causes i.a. a high microporosity and thus a high surface area of the surface modified graphite particles.

It is an aim of the present invention to address at some of the issues with the prior art.

### SUMMARY OF THE INVENTION

A first aspect of the present invention provides a method for surface-modifying carbonaceous particles, the method comprising the steps of: agglomerating carbonaceous particles by mixing the carbonaceous particles with a non-carbonized bio-based binding agent, heating the agglomerated carbonaceous particles at a rate of at least 25° C. per minute to a temperature T, and carbonizing the agglomerated carbonaceous particles at the temperature T in a gaseous environment comprising a hydrocarbon-containing gas.

According to an embodiment of the invention T is at most 950° C., preferably in the range 750-950° C.

According to another embodiment of the invention the method further comprises a step of drying the agglomerated carbonaceous particles, prior to heating the agglomerated carbonaceous particles, such that the agglomerated carbonaceous particles comprises at most 1% humidity, preferably at most 0.1% humidity.

According to yet another embodiment of the invention the bio-based binding agent is chosen from any one or more of lignin and lignosulphonate.

According to yet another embodiment of the invention the carbonaceous particles have a D50 of at most 50 microns.

According to yet another embodiment of the invention the carbonaceous particles are chosen from any one or more of natural graphite particles and synthetic graphite particles.

According to yet another embodiment of the invention the hydrocarbon-containing gas is chosen from any one or more of acetylene, ethylene, ethanol, methane, propane, and propylene.

According to yet another embodiment of the invention the concentration of the hydrocarbon-containing gas in the gaseous environment is in the range 1% 24%, preferably in the range 10%-24%.

According to yet another embodiment of the invention the step of agglomerating the carbonaceous particles with a non-carbonized bio-based binding agent comprises mixing the carbonaceous particles and the non-carbonized bio-based binding agent into an aqueous blend.

According to yet another embodiment of the invention the dry content ratio between the non-carbonized bio-based binding agent and the graphite particles in the aqueous blend is in the range 2.5-10 wt. %.

According to yet another embodiment of the invention any one or both of the step of heating the agglomerated carbonaceous particles, and the step of carbonizing the agglomerated carbonaceous particles is/are performed in a rotary kiln, paddle mixer, heat mixer or screw mixer.

According to yet another embodiment of the invention the step of carbonizing the agglomerated carbonaceous particles is performed under co-current flow conditions.

According to yet another embodiment of the invention the duration of the step of carbonizing the agglomerated carbonaceous particles in a gaseous environment is at most 45 minutes.

A second aspect of the present invention provides a graphite anode material comprising surface-modifying carbonaceous particles, wherein the surface-modifying carbonaceous particles has a SSA BET of less than 0.85 m2/g, an oxygen content of less than 0.03 wt. % and a sulphur concentration of less than 0.02 wt. %.

### BRIEF DESCRIPTION OF THE DRAWINGS

FIG. 1 is a schematic illustration of the method according to the present invention,

FIG. 2 is a table showing properties of three different surface-modified carbonaceous particles having been subjected to carbonization, sequential carbonization +hydrocarbon treatment and simultaneous carbonization+hydrocarbon treatment and

FIG. 3 is a schematic illustration of a rotary kiln, for performing the method according to the present invention.

### DETAILED DESCRIPTION OF THE INVENTION

In the following, general embodiments as well as particular exemplary embodiments of the invention will be described. References will be made to the accompanying drawings. It shall be noted, however, that the drawings are exemplary embodiments only, and that other features and embodiments may well be within the scope of the invention as claimed. Further, the mentioning of references such as “a” or “an” etc. should not be construed as excluding a plurality, and the term “disclosure” may herein be used interchangeably with the term “invention”.

Unless otherwise defined, all terms of art, notations and other scientific terms or terminology used herein are intended to have the meanings commonly understood by those of skill in the art to which this invention pertains. Certain terms of art, notations, and other scientific terms or terminology may, however, be defined specifically as indicated below.

The present invention provides a method for surface-modifying carbonaceous particles, and a graphite anode material comprising surface-modifying carbonaceous particles. The method for surface-modifying carbonaceous particles comprises a step of agglomerating carbonaceous particles by mixing the carbonaceous particles with a non-carbonized bio-based binding agent, a step of heating the agglomerated carbonaceous particles, and a step of carbonizing the agglomerated carbonaceous particles in a gaseous environment comprising a hydrocarbon-containing gas.

The method according to the present invention may thus generally comprise a step of simultaneously carbonizing and surface modifying carbonaceous particles in a gaseous environment comprising a hydrocarbon-containing gas. Said combined step has been found i.a. to result in surface-modified carbonaceous particles with improved properties relative to a process where carbonization and surface modification are performed sequentially.

A bio-based binding agent may generally herein be any bio-based material or substance that may be employed to hold or draw materials together. A bio-based material or substance may be understood as comprising materials and substances derivable from living organisms, i.e., a bio feedstock. A bio-based binding agent may more specifically be chosen from any one or more of lignin, cellulose, hemicellulose, lignosulphonate, phenolic resin, sugar, and carbohydrates/saccharide compound such as glucose, sucrose or starch.

Preferably a bio-based binding agent may be chosen from any one or more of lignin, sulphonated lignin and lignosulphonate. The latter has been found to be preferred due to cost and ease of handling. A bio-based material or substance may generally be defined as an amphiphilic organic compound.

The step of agglomerating carbonaceous particles by mixing the carbonaceous particles with a non-carbonized bio-based binding agent may for example be performed by mixing the carbonaceous particles with a non-carbonized bio-based binding agent into an aqueous blend. Said mixing may for example be performed by providing a powdered non-carbonized bio-based binding agent, mixing this powdered non-carbonized bio-based binding agent with the carbonaceous particles and adding water to the resulting mix. The latter may be performed through spraying, optionally by employing an air mixer. In another example, mixing of the carbonaceous particles with a non-carbonized bio-based binding agent may be performed by dissolving or blending the non-carbonized bio-based binding agent in/with a solvent prior to mixing with the carbonaceous particles. The solvent may for example comprise any one or more of water, pyridine, and dimethyl sulfoxide. In a particular embodiment of the present invention, the step of agglomerating the carbonaceous particles with a non-carbonized bio-based binding agent comprises mixing of the carbonaceous particles and an aqueous non-carbonized bio-based binding agent into an aqueous blend. The dry content ratio between the non-carbonized bio-based binding agent and the graphite particles in the agglomerated carbonaceous particles may generally be in the range 2.5-10 wt. %. Such ratios have been found empirically to yield an adequate agglomeration, particularly when employing lignin or lignosulfonate as a non-carbonized bio-based binding agent.

The mixing of the carbonaceous particles with a non-carbonized bio-based binding agent may according to the present invention be performed at a temperature up to 100° C., preferably in the range 50-100° C. Temperatures of at least 50-100° C. have been found to i.a. cause softening of many non-carbonized bio-based binding agents, which again has been found to ease mixing.

The step of agglomerating the carbonaceous particles by mixing the carbonaceous particles with a non-carbonized bio-based binding agent may generally herein be understood as a step of forming one or more agglomerates of carbonaceous particles, wherein an agglomerate may be understood as a collection of carbonaceous particles held together by the non-carbonized bio-based binding agent. Said agglomerates may here be at least in part held together by the adhesive properties of the non-carbonized bio-based binding agent.

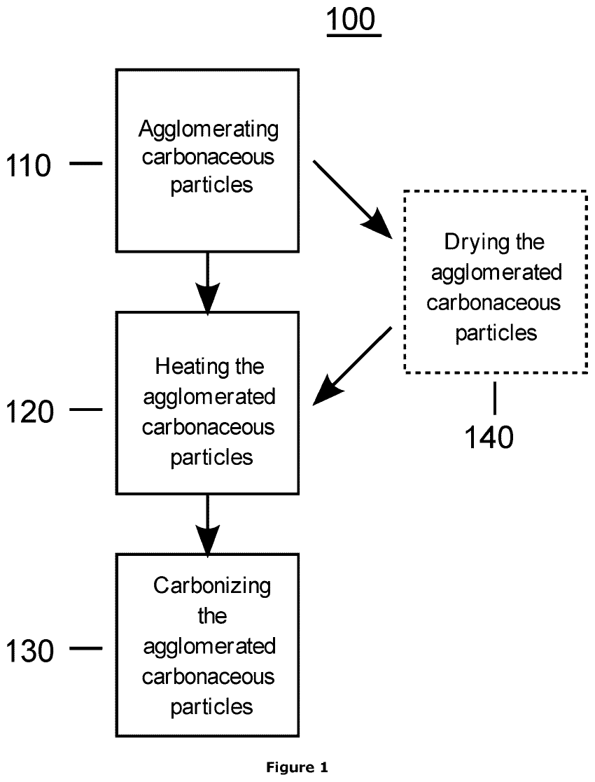

After the step of agglomerating 110 the carbonaceous particles by mixing the carbonaceous particles with a non-carbonized bio-based binding agent, the resulting agglomerated carbonaceous particles may optionally, as shown in FIG. 1, be subjected to a drying step, preferably performed at a temperature in the range 50-250° C., and more preferably in the range 80-110° C. The temperature may preferably be employed in order to reduce power consumption and may also reduce bubble formation. The method 100 according to the present invention may thus in a particular embodiment further comprise a step of drying 140 the agglomerated carbonaceous particles prior to heating 120 the agglomerated carbonaceous particles. The drying 140 step may generally be performed such that the agglomerated carbonaceous particles comprise at most 1% humidity, preferably at most 0.1% humidity. Such a level of humidity is generally chosen in order to avoid water-containing off-gas formation during the subsequent step of carbonizing 130 the agglomerated carbonaceous particles, and in order to avoid unwanted conversion of organic liquids.

The method 100 according to the present invention comprises, as schematically illustrated in FIG. 1 a step of heating 120 the agglomerated carbonaceous particles to a temperature T, followed by a step of carbonizing 130 the agglomerated carbonaceous particles at the temperature T. The step of heating 120 the agglomerated carbonaceous particles to a temperature T, and the step of carbonizing 130 the agglomerated carbonaceous particles at the temperature T are performed after the step of agglomerating 110 the carbonaceous particles by mixing the carbonaceous particles with a non-carbonized bio-based binding agent.

The temperature T may be chosen based on the type of non-carbonized bio-based binding agent that was used to agglomerate the carbonaceous particles.

The temperature T may thus generally be considered being a temperature that causes carbonization of the particular bio-based binding agent. Quantitatively, the temperature T, during the step of carbonizing the agglomerated carbonaceous particles may lie in the range 400-1500° C. Carbonization may generally be considered as a pyrolytic reaction, and the temperature T may thus be at least a temperature that causes thermal decomposition of the bio-based binding agent employed.

The step of carbonizing 130 the agglomerated carbonaceous particles may according to the present invention be performed in a gaseous environment comprising a hydrocarbon-containing gas. The temperature during carbonization 130 may cause decomposition of the hydrocarbon-containing gas into products that may condense on the agglomerated carbonaceous particles and form an adsorption layer on the agglomerated carbonaceous particles. Condensation of said products may cause a reduction of microporosity in the agglomerated carbonaceous particles, e.g., by filling cracks and/or vacant sites in the carbonaceous particles and the bio-based binding agent. The presence of a hydrocarbon-containing gas during carbonization 130 of the agglomerated carbonaceous particles may cause an in-situ filling of cracks and/or vacant sites in the agglomerated carbonaceous particles and the bio-based binding agent as these are formed. The method according to the present invention has been found to be preferable relative to a method where carbonization and surface modification are performed sequentially. As shown in FIG. 1, carbonizing 130 of agglomerated carbonaceous particles in a gaseous environment comprising a hydrocarbon-containing gas leads to a lower SSA BET and a lower oxygen content of the final surface-modified carbonaceous particle relative to a method where carbonization is performed prior to surface modification in a gaseous environment comprising a hydrocarbon-containing gas.

The step of heating the agglomerated carbonaceous particles may optionally be performed in a gaseous environment comprising a hydrocarbon-containing gas. This gaseous environment may be the same gaseous environment as the step of carbonizing the agglomerated carbonaceous particles.

Any one or more of the steps of heating the agglomerated carbonaceous particles and the step of carbonizing the agglomerated carbonaceous particles may according to the present invention be performed in a non-oxidizing environment. The non-oxidising environment may generally be an environment where no oxygen is intentionally added. An example of a non-oxidising environment is an environment constantly purged with a non-oxidizing gas, e.g., comprising any one or more of argon and nitrogen. The total oxygen concentration in said non-oxidising environment may generally be at most 0.1%, preferably at most 0.05%, and even more preferably at most 0.01%. A non-oxidizing environment is herein chosen in order to limit oxidation of the agglomerated carbonaceous particles. It will be appreciated by a person skilled in the art, however, that some unwanted oxidation during any one or more of the steps of heating the agglomerated carbonaceous particles and the step of carbonizing the agglomerated carbonaceous particles may be inevitable.

Unwanted oxidation may for example occur due to the presence of oxygen impurities in any purge gas used and/or in the hydrocarbon-containing gas, residue of moisture or air inside the equipment used to perform the heating and/or carbonizing, or leakage of air inside the equipment used to perform the heating and/or carbonizing.

The hydrocarbon-containing gas may generally according to the present invention be a single gas or a combination of different gasses. The hydrocarbon-containing gas may for example comprise any one or more of acetylene, ethylene, ethanol, methane, propane, and propylene. The hydrocarbon-containing gas may additionally comprise an inert gas, for example nitrogen or argon. As will be appreciated by a person skilled in the art with knowledge of the present invention, the concentration of the hydrocarbon-containing gas in the gaseous environment may be chosen based on the type of bio-based binding agent, the amount of bio-based binding agent, the size of the carbonaceous particles, the humidity level in the agglomerated carbonaceous particles, and the temperature T. It has empirically been found that the concentration of the hydrocarbon-containing gas in the gaseous environment may be in the range 1%-24%, preferably in the range 10%-24%.

The temperature T during the carbonizing of the agglomerated carbonaceous particles in a gaseous environment comprising a hydrocarbon-containing gas may generally be chosen according to the decomposition temperature of the hydrocarbon-containing gas. More specifically, the temperature T during the carbonizing the agglomerated carbonaceous particles at a gaseous environment comprising a hydrocarbon-containing gas may be chosen according to specific formation temperatures for various products from the decomposition of the hydrocarbon-containing gas. It has particularly been found that the decomposition of the hydrocarbon-containing gas into of polycyclic aromatic hydrocarbon may be beneficial for reducing the specific surface area of the carbonized agglomerated carbonaceous particles. Polycyclic aromatic hydrocarbons have generally been found to be formed during decomposition of a hydrocarbon containing gas at a temperature of at least 750° C., preferably at least 800° C., and more preferably at least 850° C. More specifically, polycyclic aromatic hydrocarbons have been found to be formed during decomposition of ethylene at a temperature in the range 850-1150° C., to be formed during decomposition of acetylene at a temperature in the range 800-1050° C., and to be formed during decomposition of propylene at a temperature in the range 750-1050° C. Thus, in a particular embodiment of the present invention the temperature T is chosen to be at least 750° C., at least 800° C. or at least 850° C. The temperature T may generally be chosen according to the exact hydrocarbon-containing gas that is being employed, i.e., to match the temperature during which polycyclic aromatic hydrocarbons are found to be formed during decomposition of said gas. If the hydrocarbon-containing gas comprises ethylene, the temperature T may be in the range 850-1150° C. If the hydrocarbon-containing gas comprises acetylene, the temperature T may be in the range 800-1150° C. If the hydrocarbon-containing gas comprises propylene, the temperature T may be in the range 750-1150° C.

A high heating rate of the agglomerated carbonaceous particles to a temperature suitable for inducing carbonization is generally known to cause an increased formation of defects and a large surface area in the agglomerated carbonaceous particles during the subsequent carbonization. The performance of carbonization of the agglomerated carbonaceous particles in a gaseous environment comprising a hydrocarbon-containing gas is therefore particularly preferable when a high heating rate is employed prior to carbonization. The presence of a hydrocarbon-containing gas has been found to reduce the number of defects associated with the high heating rates. The step of heating the agglomerated carbonaceous particles to a temperature T may generally be performed at a rate, R, of at least 25° C. per minute, alternatively at least 50° C. The heating rate of at least 25° C., preferably at least 50° C. per minute is particularly preferred in order reduce the processing time of surface-modifying the carbonaceous particles. A high heating rate may generally herein be considered as a heating rate of at least 25° C. per minute, alternatively be at least 50° C. In certain cases, a heating rate of above 100° C., or even 200° C. may be employed, e.g., when a rotary kiln or paddle mixer is being employed for performing the step of heating and the step of carbonizing. R may generally be chosen such that the carbonization step is considered as a fast pyrolysis.

The step of carbonizing the agglomerated carbonaceous particles, and optionally step of heating the agglomerated carbonaceous particles, may generally according to the present invention be performed in a rotary kiln, paddle mixer, heat mixer or screw mixer, preferably a rotary kiln. The employment of a type of equipment that allows for continuous stirring during the step of carbonizing the agglomerated carbonaceous particles is preferred, as the stirring enables the deposition products from the hydrocarbon-containing gas to be deposited on multiple sides of the agglomerated carbonaceous particles. Stirring during heating may be preferable in order to obtain an even effective heating rate of the agglomerated carbonaceous particles.

The step of carbonizing the agglomerated carbonaceous particles in a gaseous environment comprising a hydrocarbon-containing gas may generally be performed at a temperature in the range 400-1500° C. The upper temperature limit during the step of carbonizing the agglomerated carbonaceous particles may, however, more specifically be chosen according to the specific equipment used, acceptable equipment wear and power consumption. The inventors have found that a practical upper temperature limit during the step of carbonizing the agglomerated carbonaceous particles may be set to 950° C. 950° C. has been found to be preferable upper limit in terms of equipment wear and in terms of equipment tolerance. The temperature T may thus in an embodiment of the invention be at most 950° C.

The carbonization of the bio-based binding agent may result in the formation of certain secondary products such as polycyclic aromatic hydrocarbons, PAH, radical ions and/or alkenes. These may for example be re-adsorbed directly on the agglomerated carbonaceous particles or react with products of the hydrocarbon-containing gas before adsorbing on the agglomerated carbonaceous particles. The formation of such secondary products may thus act as an extra carbon source to occupy vacant sites and fill cracks in the agglomerated carbonaceous particles caused by carbonization. Based on the type of equipment employed to perform the step of carbonizing the agglomerated carbonaceous particles, it may thus be preferable to maintain, at least in part, such secondary products in contact with the agglomerated carbonaceous particles. The latter may for example be obtained by aligning the flow of the hydrocarbon-containing gas with the direction of movement of the agglomerated carbonaceous particles during carbonization. More specifically, the step of carbonizing the agglomerated carbonaceous particles may performed under co-current flow conditions. Co-current flow conditions may herein be understood as flow-conditions where a flow of the hydrocarbon-containing gas is maintained in contact with the agglomerated carbonaceous particles, and where the flow direction of the hydrocarbon-containing gas is maintained in parallel with the direction of moment of the agglomerated carbonaceous particles. Use of co-current flow may be particularly relevant if employing a rotary kiln or elongated paddle mixer for performing the step of carbonizing the agglomerated carbonaceous particles. The rotary kiln or elongated paddle mixer may for example be provided with a gas inlet adjacent to the inlet for the agglomerated carbonaceous particles, and a gas outlet adjacent to the outlet for the agglomerated carbonized carbonaceous particles. The flow of the hydrocarbon-containing gas may thus be maintained in parallel with, i.e., co-current with the moment of the agglomerated carbonaceous particles during the step of carbonizing the agglomerated carbonaceous particles.

FIG. 3 schematically illustrates a particular example where a rotary kiln 200 is employed in order to perform at least part of the method according to the present invention. The agglomerated carbonaceous particles may for example enter the rotary kiln 200 at an inlet 210 for the agglomerated carbonaceous particles before being introduced into a main chamber 250. The main chamber 250 may here be pre-heated, or continuously maintained at a temperature T, e.g., in order to enable the method for surface-modifying carbonaceous particles to be continuous. Upon entering the main chamber of the rotary kiln 200, the agglomerated carbonaceous particles may thus initially be heated to a temperature T before subsequently being transferred through the main chamber 250 over a predetermined time. The main chamber 250 may here be constantly purged at least in part with a hydrocarbon-containing gas, thus ensuring a hydrocarbon-containing environment inside the main chamber 250 of the rotary kiln 200. After the predetermined time, the then carbonized agglomerated carbonaceous particles are extracted from the rotary kiln 200, e.g., through an outlet 220 for the carbonized agglomerated carbonaceous particles. As schematically illustrated in FIG. 3, the rotary kiln may be provided with a gas inlet 230 adjacent to the inlet 210 for the agglomerated carbonaceous particles, and a gas outlet 240 adjacent to the outlet 220 for the agglomerated carbonized carbonaceous particles. The flow of the hydrocarbon-containing gas may thus be maintained co-current with the moment of the agglomerated carbonaceous particles inside the rotary kiln 200.

The carbonaceous particles may in a particular embodiment be graphite particles, i.e., any one or more of natural graphite particles and synthetic graphite particles. However, the method according to the present invention may generally be employed for a wider range of carbonaceous particles, comprising for example silicon carbide particles, coke particles or any mix of the aforementioned. Based on the desired application of the carbonaceous particles, the size of the carbonaceous particles may vary. Generally, the carbonaceous particles may have a D50 of at most 50 microns, optionally at most 30 microns. A D50 of at most 50 microns has been found to preferable when the carbonaceous particles are chosen from any one or more of natural graphite particles and synthetic graphite particles, particularly when the carbonaceous particles are intended for use as an anode material in a battery.

The duration of the step of carbonizing the agglomerated carbonaceous particles in a gaseous environment may generally be determined such that the bio-based binding agent is fully carbonized. As will be appreciated by a person skilled in the art with knowledge of the present invention, the exact duration of the step of carbonizing the agglomerated carbonaceous particles in a gaseous environment may vary dependent on any one or more of the types of bio-based binding agent, the amount of bio-based binding agent, the size of the carbonaceous particles, the humidity level in the agglomerated carbonaceous particles, the temperature T, and the concentration of the hydrocarbon-containing gas in the gaseous environment. In a particular embodiment of the present invention the duration of the step of carbonizing the agglomerated carbonaceous particles in a gaseous environment is at most 90 minutes, preferably at most 60 minutes, and more preferably at most 45 minutes. Said times have been found to be desirable for achieving adequate carbonization while limiting power consumption.

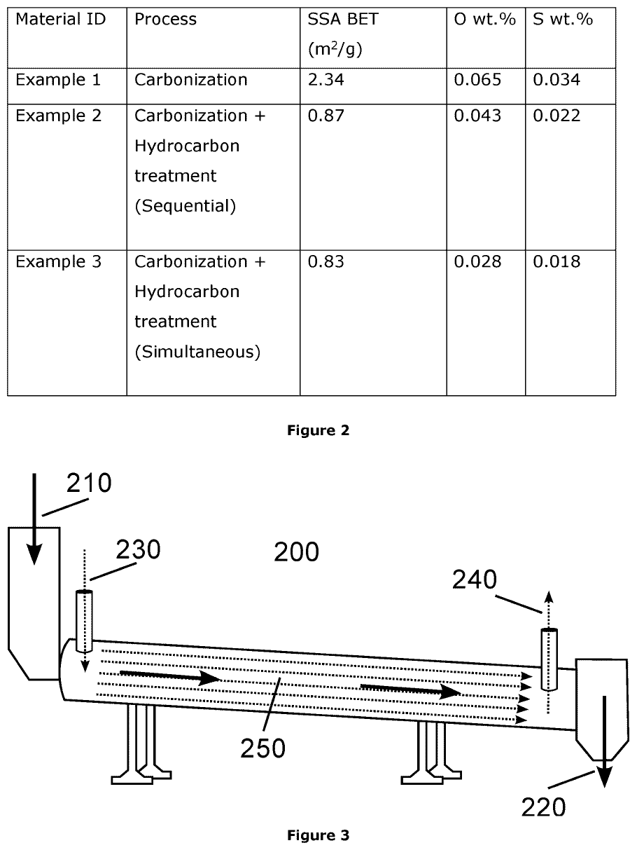

FIG. 2 shows a table of three materials, labelled examples 1-3, where example 1 has been subjected to a carbonization step, example 2 has been subjected to a carbonization step followed by a step of being exposed to a hydrocarbon-containing environment, and example 3 has been subjected to the method according to the present invention. Example 3 can here be seen to have a lower SSA BET and a lower oxygen content of the final surface-modified carbonaceous particle relative example 1 and example 2. More specifically, surface surface-modified carbonaceous particles may be obtained with a SSA BET of less than 0.85 m²/g, an oxygen content of less than 0.03 wt. % and a sulphur concentration of less than 0.02 wt. %. The present invention thus provides a graphite anode material comprising surface-modifying carbonaceous particles, wherein the surface-modifying carbonaceous particles has a SSA BET of less than 0.85 m²/g. The surface-modifying carbonaceous particles may further have any one or more of an oxygen content of less than 0.03 wt. % and a sulphur concentration of less than 0.02 wt. %. The surface-modifying carbonaceous particles may generally be obtainable by any embodiment of the method according to the present invention.

Example 1: Graphite particles were agglomerated by mixing the graphite particles with lignosulphonate and then fed into a rotary kiln preheated to temperature 850° C. The agglomerated graphite particles were then heated to 850° C. at a heating rate of at least 100° C./min. After having reached 850° C., the agglomerated graphite particles were kept at 850° C. under continuous flow of nitrogen gas for 30 minutes. The rotation and the angle of inclination are set at 3 rpm and 0.7° to get the residence time of the material in the hot zone is 30 minutes.

Example 2: Carbonized agglomerated graphite particles from example 1 were loaded into a batch rotary kiln and heated to 850° C. under inert conditions at the rate of 15° C./min, before being kept at 850° C. under continuous flow of nitrogen gas and propane gas for 30 minutes. The propane to nitrogen ratio was 0.2 and the pressure was kept at 1 atm.

Example 3: Graphite particles were agglomerated by mixing the graphite particles with lignosulphonate and then fed into a rotary kiln preheated to temperature 850° C. The agglomerated graphite particles were then heated to 850° C. at a heating rate of at least 100° C./min. After having reached 850° C., the agglomerated graphite particles were kept at 850° C. under a continuous flow of nitrogen gas and propane gas for 30 minutes. The propane to nitrogen ratio was 0.2 and the pressure was kept at 1 atm. The rotation and the angle of inclination are set at 3 rpm and 0.7° to get the residence time of the material in the hot zone is 30 minutes.

1.-14. (canceled)

15. A method for surface-modifying carbonaceous particles, the method comprising:
agglomerating carbonaceous particles by mixing the carbonaceous particles with a non-carbonized bio-based binding agent;
heating the agglomerated carbonaceous particles at a rate of at least 25° C. per minute to a temperature T; and
carbonizing the agglomerated carbonaceous particles at the temperature T in a gaseous environment comprising a hydrocarbon-containing gas.

16. The method for surface-modifying carbonaceous particles according to claim 15, wherein the temperature T is at most 950° C.

17. The method for surface-modifying carbonaceous particles according to claim 16, wherein the temperature T is at least 750° C.

18. The method for surface-modifying carbonaceous particles according to claim 15, wherein the method further comprises drying the agglomerated carbonaceous particles, prior to heating the agglomerated carbonaceous particles, such that the agglomerated carbonaceous particles comprises at most 1% humidity.

19. The method for surface-modifying carbonaceous particles according to claim 18, wherein the drying of the agglomerated carbonaceous particles is performed until the agglomerated carbonaceous particles comprise at most 0.1% humidity.

20. The method for surface-modifying carbonaceous particles according to claim 15, wherein the bio-based binding agent is chosen from any one or more of lignin and lignosulphonate.

21. The method for surface-modifying carbonaceous particles according to claim 15, wherein the carbonaceous particles have a D50 of at most 50 microns.

22. The method for surface-modifying carbonaceous particles according to claim 15, wherein the carbonaceous particles are chosen from any one or more of natural graphite particles and synthetic graphite particles.

23. The method for surface-modifying carbonaceous particles according to claim 15, wherein the hydrocarbon-containing gas is chosen from any one or more of acetylene, ethylene, ethanol, methane, propane, and propylene.

24. The method for surface-modifying carbonaceous particles according to claim 15, wherein the concentration of the hydrocarbon-containing gas in the gaseous environment is in the range 1%-24%.

25. The method for surface-modifying carbonaceous particles according to claim 24, wherein the concentration of the hydrocarbon-containing gas in the gaseous environment is in the range 10%-24%.

26. The method for surface-modifying carbonaceous particles according to claim 15, wherein agglomerating the carbonaceous particles with a non-carbonized bio-based binding agent comprises mixing the carbonaceous particles and the non-carbonized bio-based binding agent into an aqueous blend.

27. The method for surface-modifying carbonaceous particles according to claim 26, the dry content ratio between the non-carbonized bio-based binding agent and the graphite particles in the aqueous blend is in the range 2.5-10 wt. %.

28. The method for surface-modifying carbonaceous particles according to claim 15, wherein any one or both of heating the agglomerated carbonaceous particles, and carbonizing the agglomerated carbonaceous particles is/are performed in a rotary kiln, paddle mixer, heat mixer or screw mixer.

29. The method for surface-modifying carbonaceous particles according to claim 15, wherein carbonizing the agglomerated carbonaceous particles is performed under co-current flow conditions.

30. The method for surface-modifying carbonaceous particles according to claim 15, wherein the duration of the carbonizing the agglomerated carbonaceous particles in a gaseous environment is at most 45 minutes.

31. A graphite anode material comprising surface-modifying carbonaceous particles, wherein the surface-modifying carbonaceous particles has a SSA BET of less than 0.85 m²/g, an oxygen content of less than 0.03 wt. % and a sulphur concentration of less than 0.02 wt. %.
